(19) United States
(12) Patent Application Publication
(10) Pub. No.: US 2026/0353708 A1
(43) Pub. Date: Nov. 5, 2026

(54) SEMICONDUCTOR DEVICE AND METHOD OF FORMING THE SAME

(71) Applicant: HON HAI PRECISION INDUSTRY CO., LTD., New Taipei City (TW)

(72) Inventors: Chia-Lung HUNG, New Taipei City (TW); Yi-Kai HSIAO, New Taipei City (TW); Hao-Chung KUO, New Taipei City (TW); Chung-Chih LI, New Taipei City (TW); Tien-Fan OU, New Taipei City (TW); Jing-Neng YAO, New Taipei City (TW)

(21) Appl. No.: 19/554,682

(22) Filed: Mar. 3, 2026

(30) Foreign Application Priority Data
Mar. 3, 2025 (TW) 114107569

(51) Int. Cl. H10D 30/66; H10D 30/01; H10D 62/10; H10D 64/01; H10D 64/66

(52) U.S. Cl. CPC H10D 30/668; H10D 30/0297; H10D 30/665; H10D 62/107; H10D 64/018; H10D 64/021; H10D 64/675

(57) ABSTRACT

The present disclosure provides a method of forming a semiconductor device. The method comprises providing a substrate. The substrate comprises an active area and a termination area surrounding the active area. The substrate comprises an epitaxial layer and a doping area on the epitaxial layer in the active area. The method comprises etching from a top surface of the active area of the substrate to form a gate trench, wherein a bottom surface of the gate trench is lower than a bottom surface of the doping area. The method comprises forming a dielectric structure in the gate trench, wherein the dielectric structure comprises a bottom layer and a spacer disposed on the bottom layer, and the spacer has a profile protruding upwardly. The present disclosure also provides a semiconductor device.

### CROSS-REFERENCE TO RELATED APPLICATION

This application claims priority to Taiwan Application Serial Number 114107569, filed Mar. 3, 2025, which is herein incorporated by reference in its entirety.

### BACKGROUND

### Field of Invention

The present disclosure relates to a semiconductor device and method of forming the same.

### Description of Related Art

In the process of the semiconductor device, an oxide is formed at a bottom portion of a gate trench to reduce gate charge for achieving lower power dissipation and higher switching speed. If the oxide, such as low-pressure tetraethyl orthosilicate (LPTEOS), is directly deposited into the gate trench, a void is easily formed in the gate trench. An additional implantation process is performed to solve the above problem, inducing the process more complex.

### SUMMARY

The present disclosure provides a method of forming a semiconductor device. The method includes providing a substrate, wherein the substrate includes an active area and a termination area surrounding the active area, and the substrate includes an epitaxial layer and a doping area on the epitaxial layer in the active area. The method includes etching from a top surface of the active area of the substrate to form a gate trench, wherein a bottom surface of the gate trench is lower than a bottom surface of the doping area. The method includes forming a dielectric structure in the gate trench, wherein the dielectric structure includes a bottom layer and a spacer disposed on the bottom layer, and the spacer has a profile protruding upwardly.

The present disclosure provides a semiconductor device. The semiconductor device includes a substrate including an active area and a termination area surrounding the active area, an epitaxial layer on the substrate and distributed in the active area and the termination area, a first doping region on the epitaxial layer in the active area, a second doping region on the epitaxial layer in the termination area, a gate structure in the first doping region and a portion of the epitaxial layer. The gate structure includes a dielectric structure and a conductive structure on the dielectric structure. The dielectric structure includes a bottom layer and a spacer on the bottom layer and having a protruding profile in a direction perpendicular to the substrate. The bottom layer includes low-pressure tetraethyl orthosilicate (LPTEOS), and the spacer includes borophosphosilicate glass (BPSG).

It is to be understood that both the foregoing general description and the following detailed description are by examples, and are intended to provide further explanation of the present disclosure as claimed.

### BRIEF DESCRIPTION OF THE DRAWINGS

The present disclosure can be more fully understood by reading the following detailed description of the embodiment, with reference made to the accompanying drawings as follows:

FIGS. 1-6 are cross-section views of a method of forming a semiconductor device at different stages according to some embodiments of the present disclosure, respectively.

FIGS. 7-8 are enlarged views of an area in FIG. 6 according to different embodiments of this present disclosure, respectively.

FIG. 9 is a cross-section view of a semiconductor device according to some embodiments of the present disclosure.

### DETAILED DESCRIPTION

Reference will now be made in detail to the present embodiments of the present disclosure, examples of which are illustrated in the accompanying drawings. Wherever possible, the same reference numbers are used in the drawings and the description to refer to the same or like parts.

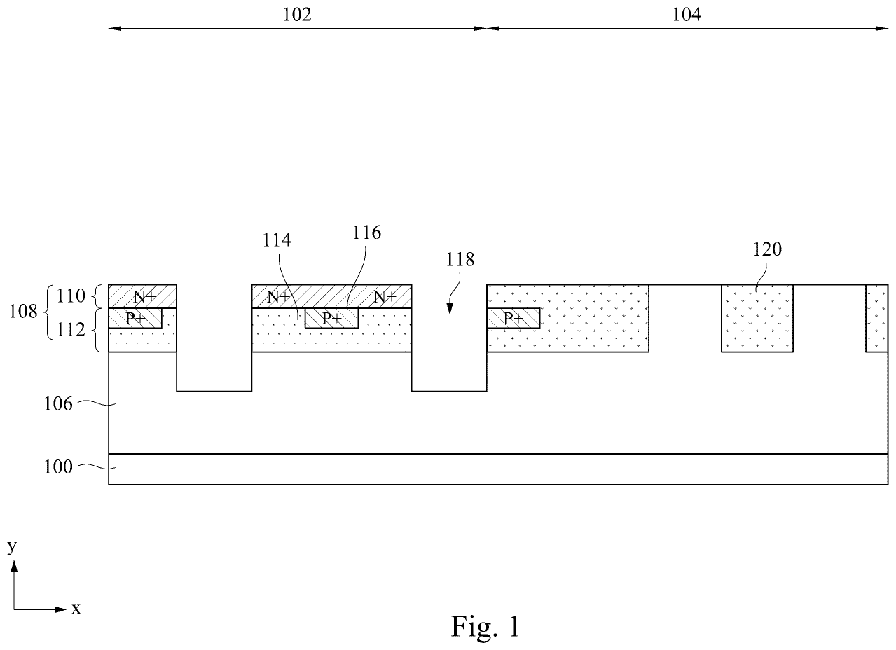

Referring to FIG. 1, a substrate 100 is provided. The substrate 100 includes an active area 102 and a termination area 104 surrounding the active area 102. An epitaxial layer 106 is formed on the substrate 100 and distributed in the active area 102 and the termination area 104. In some embodiments, the epitaxial layer 106 may be an n-type doped epitaxial layer. A first doping region 108 is formed in a top portion of the epitaxial layer 106 in the active area 102. The first doping region 108 includes a well region 112 and a source region 110 on the well region 112. The source region 110 may be an n-type doped region. The well region 112 includes a p-type doped region 114 and a p-type heavy doped region 116 on the p-type doped region 114, and the source region 110 overlies the p-type doped region 114 and the p-type heavy doped region 116. In some embodiments, a doping concentration of the p-type heavy doped region 116 is higher than a doping concentration of p-type doped region 114. In some embodiments, a top surface of the p-type doped region 114 is level with a top surface of the p-type heavy doped region 116. A second doping region 120 is formed in a top portion of the epitaxial layer 106 in the termination area 104. The second doping region 120 may be as a p-type doped guiding ring, and the second doping region 120 and the epitaxial layer 106 form a PN junction to prevent from generating leakage current in an x direction. In some embodiments, a bottom surface of the second doping region 120 is level with a bottom surface of the well region 112 in the first doping region 108.

Continuing to FIG. 1, a gate trench 118 is formed in the epitaxial layer 106 in the active area 102. The gate trench 118 extends from a top surface of the first doping region 108 to the epitaxial layer 106. After the formation of the gate trench 118, a top portion of the gate trench 118 is surrounded by the first doping region 108 and the second doping region 120 in the x direction. In some embodiments, a bottom surface of the gate trench 118 is lower than a bottom surface of the well region 112 in the first doping region 108. In some embodiments, the formation of the gate trench 118 is performed by such as reactive etching (RIE), wet etching, plasma etching and inductively coupled plasma (CIP) etching.

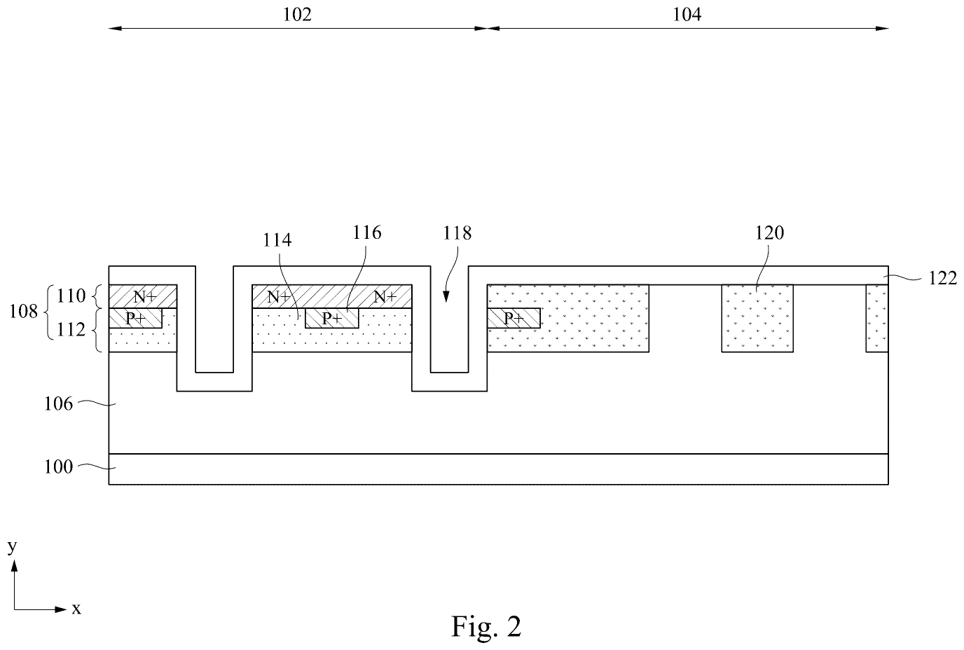

Referring to FIG. 2, a first oxide layer 122 is deposited conformally on the top surface of the epitaxial layer 106, the first doping region 108 and the second doping region 120 and in the gate trench 118. The first oxide layer 122 is distributed in the active area 102 and the termination area 104. A material of the first oxide layer 122 may be, for example, low-pressure tetraethyl orthosilicate (LPTEOS). A thickness of the first oxide layer 122 may be in a range from about 2000 A to about 8000 A. If the thickness of the first oxide layer 122 is lower than 2000 A, the thickness of the first oxide layer 122 on a sidewall of the gate trench 118 may be too thin, causing atoms, such as phosphorous and boron, in the second oxide layer 124 (following formed) diffused to the sidewall of the gate trench 118, thereby influencing properties and reliability of the device. If the thickness of the first oxide layer 122 is higher than 8000 A, a void may be formed in the gate trench 118, causing a structure of a bottom layer 132 of a dielectric structure 136 (following formed) destroyed by the sequentially etching along the void. The thickness of the first oxide layer 122 may control a profile of the dielectric structure 136 following formed. In some embodiments, the first oxide layer 122 may be formed comformally by the deposition method, such as chemical vapor deposition (CVD), physical vapor deposition (PVD), atomic layer deposition (ALD), low-pressure CVD (LPCVD), plasma-enhanced chemical vapor deposition (PECVD).

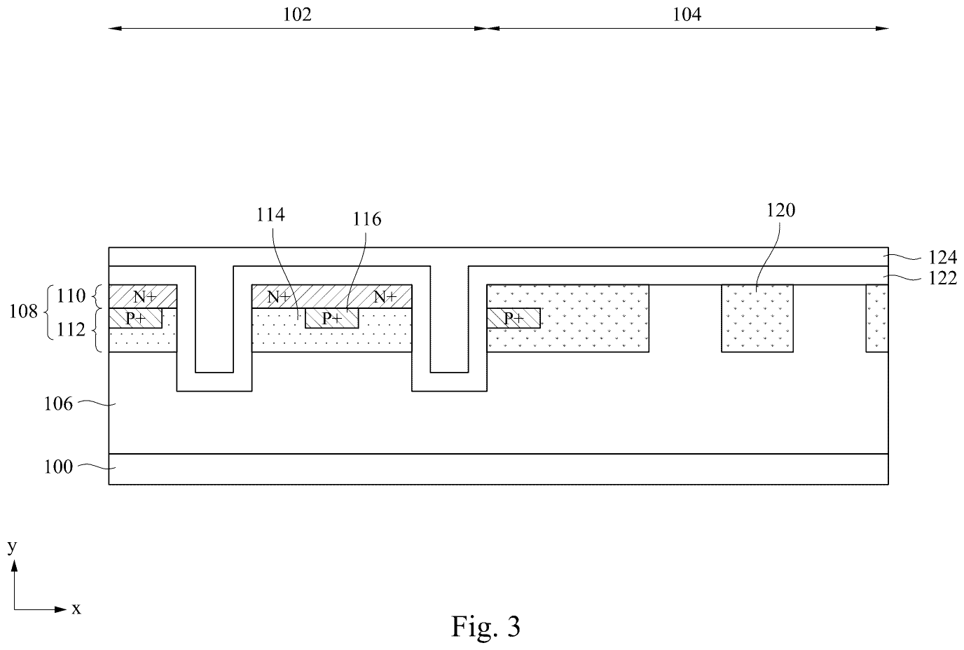

Referring to FIG. 3, a second oxide layer 124 is formed on the first oxide layer 122. The second oxide layer 124 is distributed in the active area 102 and the termination area 104. The second oxide layer 124 fills the gate trench 118 (as shown in FIG. 2) and overlies the first oxide layer 122. A material of the second oxide layer 124 may be, for example, borophosphosilicate glass (BPSG). In some embodiments, a second oxide material may be deposited by the deposition method, such as CVD, PVD, ALD and electron beam evaporation, then a planarization process is performed to the second oxide material to form the second oxide layer 124. The planarization process may be chemical mechanical planarization (CMP), anisotropic etch, high temperature thermal reflow or the combinations of thereof.

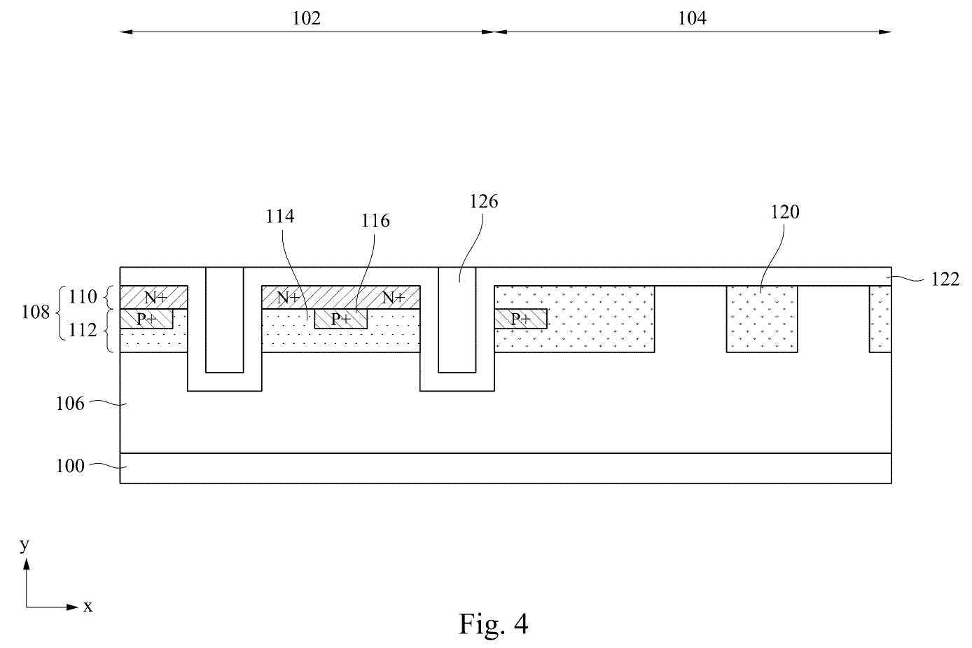

Referring to FIG. 4, a portion of the second oxide layer 124 on the first oxide layer 122 is removed, such that the remained second oxide layer 124 in the gate trench 118 forms a second oxide 126. The first oxide layer 122 on the top surface of the first doping region 108, the second doping region 120 and the epitaxial layer 106 is exposed, such that a top surface of the first oxide layer 122 is level with a top surface of the second oxide 126. In some embodiments, the removal of the second oxide layer 124 may be performed by wet etching process with etchants, and the etchants may be, for example, buffered oxide etch (BOE).

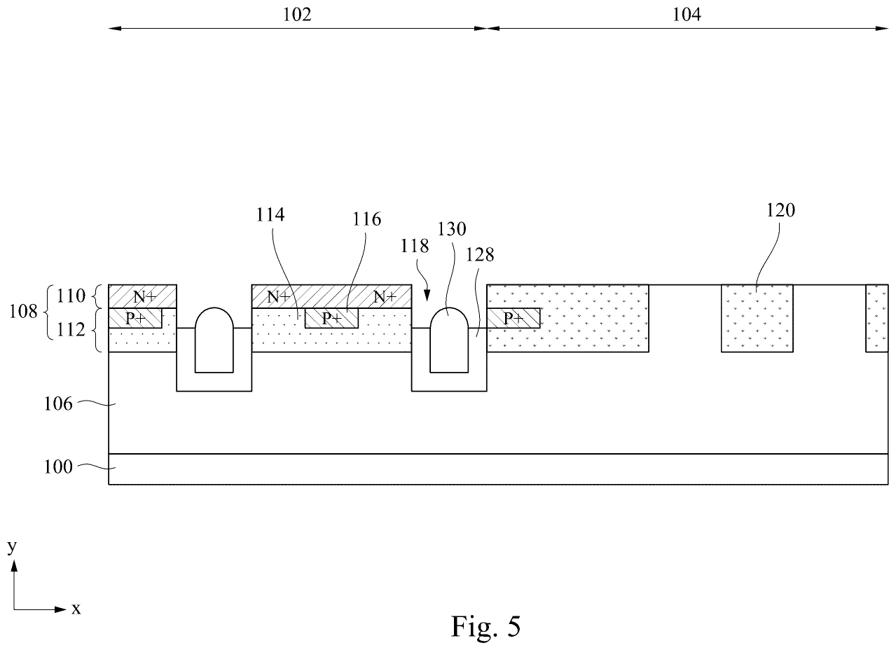

Referring to FIG. 5, a wet etching process is performed to remove a portion of the first oxide layer 122 and a portion of the second oxide 126 to form a first oxide 128 and a second oxide 130 in the gate trench 118. The portion of the first oxide layer 122 on the top surface of the first doping region 108, the second doping region 120 and the epitaxial layer 106 and in the top portion of the gate trench 118 is removed to form the first oxide 128. The portion of the second oxide 126 in the top portion of the gate trench 118 is removed to form the second oxide 130, such that a bottom portion of the second oxide 130 is surrounded by the first oxide 128. After the wet etching process is performed, the second oxide 130 has a profile protruding upwardly in a direction perpendicular to the substrate 100. In some embodiments, a topmost horizontal plane of the second oxide 130 is higher than a horizontal plane of a top surface of the first oxide 128, and the top surface of the first oxide 128 is lower than a bottom surface of the source region 110. In some embodiments, for example, the buffered oxide etch (BOE) may be used in the wet etching process.

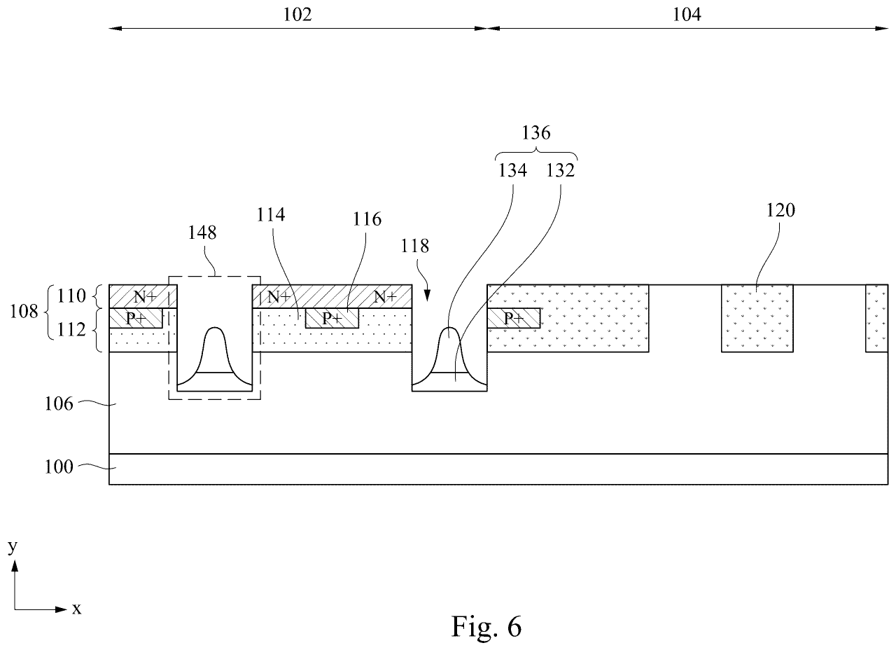

Referring to FIG. 6, the wet etching process is performed to remove a portion of the first oxide 128 and a portion of the second oxide 130, such that the remained first oxide 128 and the remained second oxide 130 in a bottom portion of the gate trench 118 form the dielectric structure 136. The dielectric structure 136 includes the bottom layer 132 and a spacer 134 on the bottom layer 132. The portion of the first oxide 128 is removed to form the bottom layer 132, and the portion of the second oxide 130 is removed to form the spacer 134. A top surface of the bottom layer 132 is lower than the bottom surface of the well region 112 of the first doping region 108, and a topmost horizontal plane of the spacer 134 is lower than the bottom surface of the source region 110.

After the wet etching is performed, the spacer 134 has a profile protruding upwardly in the direction perpendicular to the substrate 100 (e.g., y direction), and a cross-section (e.g., x-y plane) of the profile may have a sharp, round corner or curve shape. The shape of the profile may be controlled by adjusting the thickness of the first oxide layer 122 (as shown in FIG. 4). For example, if the thicker first oxide layer 122 is deposited (e.g., 3000 A), the spacer 134 may have a sharp shaped profile. For example, if the thinner first oxide layer 122 is deposited (e.g., 2000 A), the spacer 134 may have a curve (flat) profile.

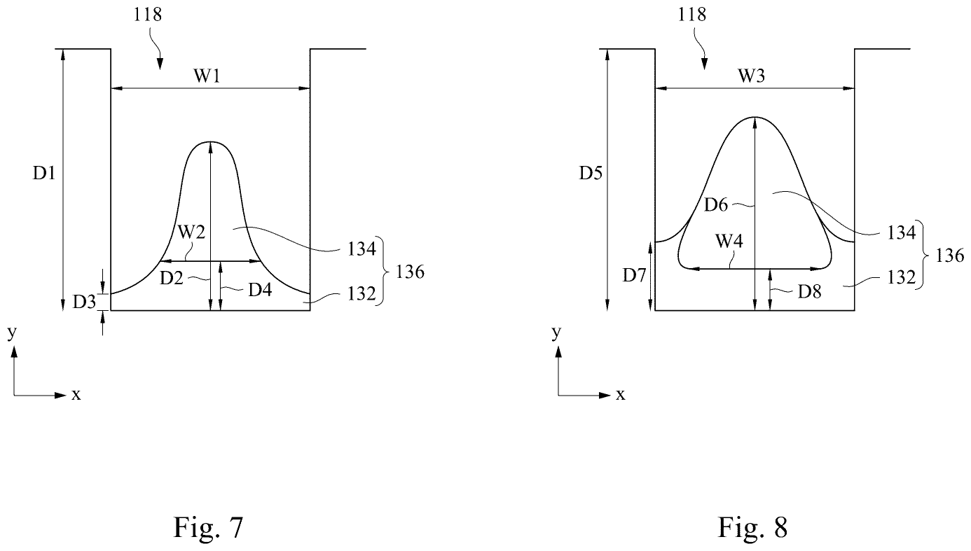

Referring to FIG. 7, FIG. 7 is illustrated an enlarged view of an area 148 of the dielectric structure 136 in the gate trench 118 as described in FIG. 6. A depth D1 of the gate trench 118 is defined from the top surface of the active area 102 extending downwardly, and a dimension D2 is defined between the topmost horizontal plane of the spacer 134 and the bottom surface of the gate trench 118. In some embodiments, the dimension D2 may be in a range from about 5000 A to 10000 A. If the dimension D2 is too low, it may influence the pressure ability of the device. The dimension D2 may not exceed the depth D1. A ratio of the dimension D2 to the depth D1 may be in a range from 40% to 80%. In addition, the top surface of the bottom layer 132 between the sidewall of the gate trench 118 and the spacer 134 has a bottommost horizontal plane. A dimension D3 is defined between the bottommost horizontal plane and the bottom surface of the gate trench 118. In some embodiments, a ratio of the dimension D3 to the dimension D2 is in a range from 60% to 80%. If the dimension D3 is too low, it may influence the pressure ability of the device. The dimension D3 may not exceed the dimension D2. Further, a dimension D4 is defined between a bottom surface of the spacer 134 and the bottom surface of the gate trench 118. In some embodiments, a ratio of the dimension D4 to the dimension D3 may be in a range from 100% to 200%, and the dimension D4 may not be smaller than the dimension D3. In some embodiments, a ratio of the dimension D4 to the dimension D2 may be in a range from 20% to 80%. On the other hand, a width W1 of the gate trench 118 is defined in a direction parallel to the substrate 100 (e.g., x direction). A width W2 of the bottom surface of the spacer 134 is defined in the direction parallel to the substrate 100 (e.g., x direction). In some embodiments, a ratio of the width W2 to the width W1 is in a range from 50% to 80%. If the width W2 is too narrow, it may influence the ability of trench filling of a gate material later. The width W2 may not exceed the width W1.

Referring the FIG. 8, FIG. 8 is illustrated other embodiments of the dielectric structure 136. After the portion of the first oxide 128 (as shown in FIG. 5) is removed by wet etching, a top surface of the resulting bottom layer 132 between the sidewall of the gate trench 118 and the spacer 134 is higher than the bottom surface of the spacer 134. In other words, the bottom layer 132 surrounds a bottom portion of the spacer 134.

Continuing to FIG. 8, a depth D5 of the gate trench 118 is defined from the top surface of the active area 102 extending downwardly, and a dimension D6 is defined between a topmost horizontal plane of the spacer 134 and the bottom surface of the gate trench 118. In some embodiments, the dimension D6 may be in a range from about 5000 A to 10000 A. A ratio of the dimension D6 to the depth D5 may be in a range from 40% to 80%. The top surface of the bottom layer 132 of the dielectric structure 136 between the sidewall of the gate trench 118 and the spacer 134 has a bottommost horizontal plane. A dimension D7 is defined between the bottommost horizontal plane and the bottom surface of the gate trench 118, and a dimension D8 is defined between a bottom surface of the spacer 134 and the bottom surface of the gate trench 118. In some embodiments, a ratio of the dimension D7 to the dimension D8 may be in a range from 100% to 200%, and the dimension D7 may not be smaller than the dimension D8. On the other hand, a width W3 of the gate trench 118 is defined in a direction parallel to the substrate 100 (e.g., x direction). A width W4 of the bottom surface of the spacer 134 is defined in the direction parallel to the substrate 100 (e.g., x direction). In some embodiments, a ratio of the width W4 to the width W3 is in a range from 50% to 80%. If the width W4 is too narrow, it may influence the ability of trench filling of the gate material later. The width W4 may not exceed the width W3

In some embodiments, the dielectric structure 136 may be formed by first depositing a first oxide material (e.g., LPTEOS) overfilling the gate trench 118, then removing a portion of the first oxide material. However, depositing the first oxide material overfilling the gate trench 118 may form the void in the gate trench 118, and the void in the gate trench 118 is not desired. Therefore, an additional implantation process (e.g., Ar implant) is performed to form a specific shape oxide in the bottom portion of the gate trench 118. The method of forming the semiconductor device described in the present disclosure includes depositing LPTEOS and BPSG in the gate trench 118 first, then performing the wet etching process, without performing additional implantation process to achieve the specific shape oxide in the bottom portion of the gate trench 118. Further, the profile of the oxide is adjusted with LPTEOS.

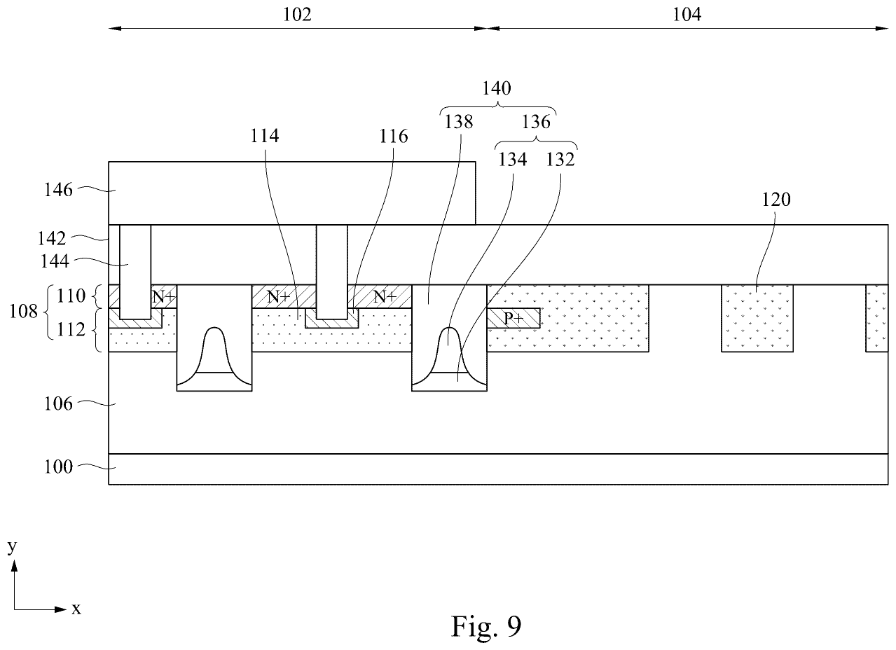

Referring to FIG. 9, a gate structure 140 is formed in the gate trench 118 (as shown in FIG. 6). The gate structure 140 includes a conductive structure 138 and the dielectric structure 136. The conductive structure 138 may be formed by depositing a conductive material overfilling the gate trench 118, then removing a portion of the conductive material on the top surface of the first doping region 108, the second doping region 120 and the epitaxial layer 106. In some embodiments, a material of the conductive structure 138 may be polysilicon as a gate electrode, to perform gate switching by applying different bias voltages. Since the gate structure 140 includes the dielectric structure 136, such that a volume of the conductive structure 138 as the gate electrode may be reduced. In some embodiments, a volume ratio of the dielectric structure 136 to the gate structure 140 may be in a range from 20% to 70%, such that the dielectric structure 136 may effectively protect a thin oxide (not shown) located on the sidewall of the gate trench 118, preventing from the device destroyed. However, if the volume ratio of the dielectric structure 136 to the gate structure 140 is too high, it may compress the size of the conductive structure 138, such that the device may not be controlled by the gate structure 140.

Next, an insulating layer 142 overlies on the top surface of the first doping region 108, the second doping region 120, the epitaxial layer 106 and the gate structure 140, and is distributed in the active area 102 and the termination area 104. Next, a plug 144 is formed in the insulating layer 142 in the active area 102. The plug 144 is connected to the first doping region 108 through the insulating layer 142. A material of the plug 144 may be the conductive material, such as tungsten (W). After the formation of the plug 144, a source metal layer 146 is formed on the insulating layer 142 in the active area 102. The source metal layer 146 overlies the top surface of the insulating layer 142 and the plug 144 in the active area 102, such that the source metal layer 146 is connected to the first doping region 108 through the plug 144.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this present disclosure provided they fall within the scope of the following claims.

What is claimed is:

1. A method of forming a semiconductor device, comprising:
providing a substrate, wherein the substrate comprises an active area and a termination area surrounding the active area, and the substrate comprises an epitaxial layer and an doping region on the epitaxial layer in the active area;
etching from a top surface of the active area of the substrate to form a gate trench, wherein a bottom surface of the gate trench is lower than a bottom surface of the doping region; and
forming a dielectric structure in the gate trench, wherein the dielectric structure comprises a bottom layer and a spacer disposed on the bottom layer, and the spacer has a profile protruding upwardly.

2. The method of claim 1, further comprising:
forming a gate structure in the gate trench, wherein a volume ratio of the dielectric structure to the gate structure is in a range from 20% to 70%.

3. The method of claim 1, wherein a material of the bottom layer comprises low-pressure tetraethyl orthosilicate (LPTEOS), and a material of the spacer comprises borophosphosilicate glass (BPSG).

4. The method of claim 1, wherein forming the dielectric structure in the gate trench comprises:
conformally depositing a first oxide layer in the gate trench;
depositing a second oxide layer on the first oxide layer; and
removing a portion of the first oxide layer and the second oxide layer.

5. The method of claim 1, wherein a top surface of the bottom layer is lower than the bottom surface of the doping region.

6. The method of claim 1, wherein the profile has a sharp, round corner or curve shape.

7. The method of claim 1, wherein a distance is defined between a topmost horizontal plane of the spacer and the bottom surface of the gate trench is in a range from 5000 A to 10000 A.

8. The method of claim 1, wherein a dimension is defined between a topmost horizontal plane of the spacer and the bottom surface of the gate trench, a depth of the gate trench is defined from the top surface of the active area of the substrate extending downwardly, and a ratio of the dimension to the depth is in a range from 40% to 80%.

9. The method of claim 1, wherein a top surface of the bottom layer between a sidewall of the gate trench and the spacer has a bottommost horizontal plane, a first dimension is defined between the bottommost horizontal plane and the bottom surface of the gate trench, a second dimension is defined between a topmost horizontal plane of the spacer and the bottom surface of the gate trench, and a ratio of the first dimension to the second dimension is in a range from 60% to 80%.

10. The method of claim 1, wherein a first width of the gate trench is defined in a direction parallel to the substrate, a second width of the bottom surface of the spacer is defined in the direction parallel to the substrate, and a ratio of the second width to the first width is in a range from 50% to 80%.

11. The method of claim 1, wherein a top surface of the bottom layer between a sidewall of the gate trench and the spacer has a bottommost horizontal plane, a first dimension is defined between the bottommost horizontal plane and the bottom surface of the gate trench, a third dimension is defined between a bottom surface of the spacer and the bottom surface of the gate trench, and a ratio of the third dimension to the first dimension is in a range from 100% to 200%.

12. The method of claim 1, wherein the bottom layer further surrounds a bottom portion of the spacer.

13. The method of claim 12, wherein a top surface of the bottom layer between a sidewall of the gate trench and the spacer has a bottommost horizontal plane, a fourth dimension is defined between the bottommost horizontal plane and the bottom surface of the gate trench, a fifth dimension is defined between a bottom surface of the spacer and the bottom surface of the gate trench, and a ratio of the fourth dimension to the fifth dimension is in a range from 100% to 200%.

14. A semiconductor device, comprising:
a substrate comprising an active area and a termination area surrounding the active area;
an epitaxial layer on the substrate and distributed in the active area and the termination area;
a first doping region on the epitaxial layer in the active area;
a second doping region on the epitaxial layer in the termination area; and
a gate structure in the first doping region and a portion of the epitaxial layer, wherein the gate structure comprises:
a dielectric structure; and
a conductive structure on the dielectric structure, wherein the dielectric structure comprises:
a bottom layer; and
a spacer on the bottom layer and having a protruding profile in a direction perpendicular to the substrate, wherein the bottom layer comprises low-pressure tetraethyl orthosilicate (LPTEOS), and the spacer comprises borophosphosilicate glass (BPSG).

15. The semiconductor device of claim 14, wherein the bottom layer comprises a thickness in a range from 2000 A to 8000 A in the direction.

16. The semiconductor device of claim 14, wherein a second dimension is defined between a topmost horizontal plane of the spacer and a bottom surface of the gate structure, a third dimension is defined between a bottom surface of the spacer and the bottom surface of the gate structure, and a ratio of the third dimension to the second dimension is in a range from 20% to 80%.
